(19) United States
(12) Patent Application Publication
(10) Pub. No.: US 2018/0096967 A1
(43) Pub. Date: Apr. 5, 2018

(54) ELECTRONIC PACKAGE STRUCTURE AND METHOD FOR FABRICATING THE SAME

(71) Applicant: Siliconware Precision Industries Co., Ltd., Taichung (TW)

(72) Inventors: Wen-Jung Tsai, Taichung City (TW); Cheng-Kai Chang, Taichung City (TW); Yen-Hung Lin, Taichung City (TW); Hsin-Lung Chung, Taichung City (TW)

(21) Appl. No.: 15/435,437

(22) Filed: Feb. 17, 2017

(30) Foreign Application Priority Data
Sep. 30, 2016 (TW) 105131574

(51) Int. Cl. H01L 25/065; H01L 23/31; H01L 23/58; H01L 25/00

(52) U.S. Cl. CPC H01L 25/0652; H01L 25/50; H01L 23/585; H01L 23/3121

(57) ABSTRACT

An electronic package structure is provided, which includes: a plurality of first and second electronic components disposed on opposite sides of a carrier; a blocking member formed between adjacent two of the first electronic components; an encapsulant encapsulating the first and second electronic components and the blocking member; and a shielding element formed on the encapsulant to improve the electromagnetic shielding effect. The present disclosure further provides a method for fabricating the electronic package structure.

### BACKGROUND

### 1. Technical Field

The present disclosure relates to electronic package structures and methods for fabricating the same, and, more particularly, to an electronic package structure having an electromagnetic shielding function and a method for fabricating the same.

### 2. Description of Related Art

Along with the rapid development of electronic industries, electronic products are developed towards the trend of multi-function and high performance. To meet the requirements of multi-function and high performance of electronic products, a semiconductor package is required to have a plurality of chips to be disposed therein.

However, such a conventional semiconductor package lacks an electromagnetic interference (EMI) shielding function. Consequently, the chips may be subjected to external EMI or electromagnetically interfere with one another, thus adversely affecting the overall electrical efficiency and even resulting in product failure.

Therefore, there is a need to provide an electronic package structure and a fabrication method thereof so as to overcome the above-described drawbacks.

### SUMMARY

In view of the above-described drawbacks, the present disclosure provides an electronic package structure, which comprises: a carrier having a first side and a second side opposite to the first side; a plurality of first electronic components disposed on the first side of the carrier; at least one second electronic component disposed on the second side of the carrier; a blocking member disposed on the first side of the carrier between adjacent two of the first electronic components; and an encapsulant formed on the first side and the second side of the carrier and encapsulating the first electronic components, the second electronic component and the blocking member.

The present disclosure further provides a method for fabricating an electronic package structure, which comprises: providing a carrier having a first side and a second side opposite to the first side; disposing a plurality of first electronic components on the first side of the carrier, and disposing at least one second electronic component on the second side of the carrier; disposing a blocking member on the first side of the carrier between adjacent two of the first electronic components; and forming on the first side and the second side of the carrier an encapsulant encapsulating the first electronic components, the second electronic component and the blocking member.

The present disclosure further provides another method for fabricating an electronic package structure, which comprises: providing a carrier having a first side and a second side opposite to the first side; disposing a plurality of first electronic components on the first side of the carrier, and disposing at least one second electronic component on the second side of the carrier; forming on the first side and the second side of the carrier an encapsulant encapsulating the first and second electronic components; forming a groove in the encapsulant between adjacent two of the first electronic components, wherein a surface of the first side of the carrier is partially exposed from the groove; and forming a blocking member in the groove.

In an embodiment, the blocking member is disposed in the groove by sputtering.

In an embodiment, the carrier has a through hole communicating the first side with the second side, and the encapsulant is further formed in the through hole of the carrier.

In an embodiment, at least one of the first electronic components is an active element, a passive element, a package, or a combination thereof.

In an embodiment, the second electronic component is an active element, a passive element, a package, or a combination thereof.

In an embodiment, a shielding element is further disposed on the encapsulant and electrically connected to the carrier. In another embodiment, the carrier has a grounding portion formed on a side surface thereof, and the shielding element extends to the side surface of the carrier so as to come into contact with the grounding portion. In yet another embodiment, the shielding element is electrically connected to the blocking member. In further another embodiment, the shielding element is not electrically connected to the blocking member.

In an embodiment, the shielding element is a conductive layer formed on the encapsulant by sputtering.

In an embodiment, the shielding element is a conductive lid covering the encapsulant.

In an embodiment, the blocking member is made of a conductive material and electrically connected to the carrier.

In an embodiment, the shielding element and the blocking member are integrally formed.

According to the present disclosure, the encapsulant flows through the through hole of the carrier to encapsulate the first electronic components, the blocking member and the second electronic component. As such, only a single encapsulating process is required, thereby greatly reducing the fabrication steps and cost.

Further, the shielding element disposed around an outer periphery of the first and second electronic components effectively prevents external electromagnetic waves from interfering with internal circuits of the first and second electronic components.

Furthermore, the blocking member positioned between adjacent two of the first electronic components prevents electromagnetic interference from occurring between the first electronic components.

In addition, a double-side molding process facilitates miniaturization of the electronic package structure.

### BRIEF DESCRIPTION OF DRAWINGS

FIGS. 1A to 1D are schematic cross-sectional views showing a method for fabricating an electronic package structure according to a first embodiment of the present disclosure;

FIG. 2 is a schematic upper view showing an arrangement of components of FIG. 1B;

FIG. 3 is a schematic cross-sectional view showing another embodiment of FIG. 1D; and

FIGS. 4A and 4B are schematic cross-sectional views showing a method for fabricating an electronic package structure according to a second embodiment of the present disclosure.

### DETAILED DESCRIPTION

The following illustrative embodiments are provided to illustrate the disclosure of the present disclosure, these and other advantages and effects can be apparent to those in the art after reading this specification.

It should be noted that all the drawings are not intended to limit the present disclosure. Various modifications and variations can be made without departing from the spirit of the present disclosure. Further, terms such as “first”, “second”, “on”, “a” etc. are merely for illustrative purposes and should not be construed to limit the scope of the present disclosure.

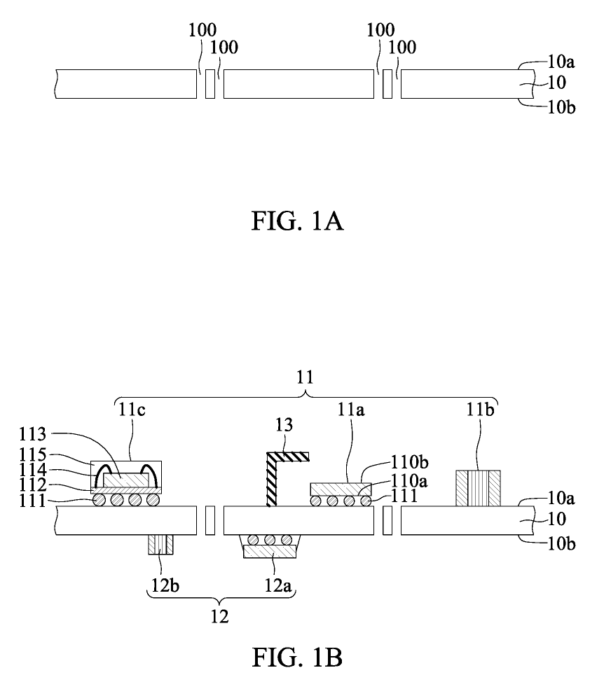

FIGS. 1A to 1D are schematic cross-sectional views showing a method for fabricating an electronic package structure 1 according to a first embodiment of the present disclosure. In an embodiment, the electronic package structure 1 is a system-in-package (SiP) RF module.

Referring to FIG. 1A, a carrier 10 having a first side 10a and an opposite second side 10b is provided.

In an embodiment, the carrier 10 has a plurality of through holes 100 communicating the first side 10a with the second side 10b.

In an embodiment, the carrier 10 is, but not limited to, a core or coreless circuit board, a lead frame, a ceramic board, or a metal board. A circuit layer (not shown) is optionally formed on a surface of the carrier 10.

Referring to FIG. 1B, a plurality of first electronic components 11 and a blocking member 13 are disposed on the first side 10a of the carrier 10, and a plurality of second electronic components 12 are disposed on the second side 10b of the carrier 10.

In an embodiment, at least one of the first electronic components 11 is an active element 11a such as a semiconductor chip, a passive element 11b, such as a resistor, a capacitor and an inductor, a package 11c, or a combination thereof.

In an embodiment, the active element 11a is an RF chip or other semiconductor chip, such as a Bluetooth chip or a Wi-Fi chip. The active element 11a has an active surface 110a and an inactive surface 110b opposite to the active surface 110a, and is disposed on the circuit layer of the carrier 10 in a flip-chip manner via the active surface 110a. The package 11c is electrically connected to the circuit layer of the carrier 10 through a plurality of solder bumps 111. The package 11c has a packaging substrate 112, at least one chip 113 disposed on the packaging substrate 112 and electrically connected to the packaging substrate 112 through a plurality of bonding wires 114 (or solder bumps, not shown), and an encapsulant 115 encapsulating the chip 113 and the bonding wires 114.

In an embodiment, at least one of the second electronic components 12 is an active element 12a such as a semiconductor chip, a passive element 12b, such as a resistor, a capacitor and an inductor, a package (not shown), or a combination thereof.

The first electronic components 11 and the second electronic components 12 can be RF modules, such as WLAN, GPS, Bluetooth, DVB-H or FM communication modules.

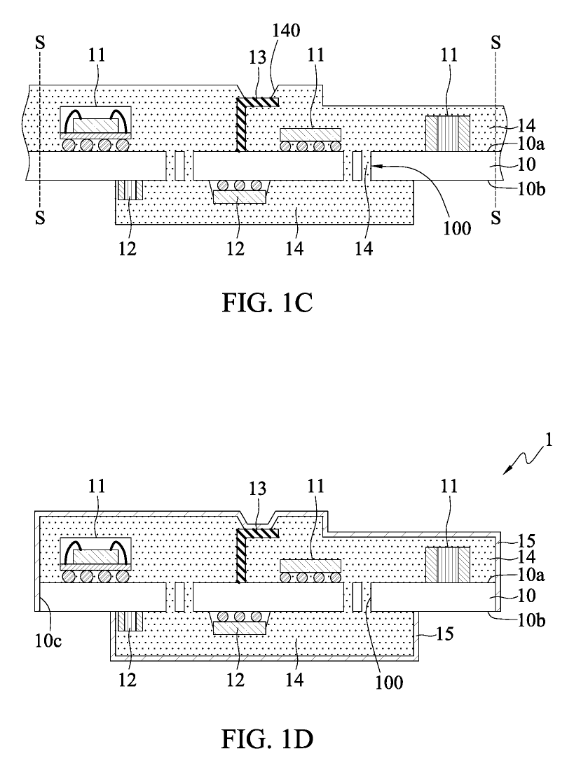

The blocking member 13 is made of a conductive material, such as Cu, Ni, Au, Fe, Al or an alloy thereof. Referring to FIGS. 1B and 2, the blocking member 13 is vertically disposed on the first side 10a of the carrier 10 between adjacent two of the first electronic components 11 (e.g., the package 11c and the active element 11a) to block one side of each of the two first electronic components 11 and prevent EMI from occurring between the two first electronic components 11, thereby ensuring proper operation of the two first electronic components 11.

Referring to FIG. 1C, an encapsulant 14 is formed on the first side 10a and the second side 10b and in the through holes 100 of the carrier 10 and encapsulates the first electronic components 11, the blocking member 13 and the second electronic components 12. In an embodiment, a portion of a surface of the blocking member 13 is exposed from the encapsulant 14.

In an embodiment, the encapsulant 14 is made of a molding compound, a dry film, polyimide, or an epoxy resin. The encapsulant 14 can be formed by molding or laminating. Alternatively, the encapsulant 14 can be formed by dispensing and then dried.

Optionally, an opening 140 is formed in the encapsulant 14 to expose the portion of the surface of the blocking member 13. Alternatively, an upper surface of the blocking member 13 can be flush with an upper surface of the encapsulant 14 so as to be exposed from the encapsulant 14.

There are various methods for fabricating the encapsulant 14 and the blocking member 13. In an embodiment, the encapsulant 14 is formed first, then at least one through hole is formed in the encapsulant 14, and a conductive material such as copper is filled in the through hole of the encapsulant 14 to form the blocking member 13. In another embodiment, the blocking member 13 can be formed together with a shielding element 15 (to be described later).

In an embodiment, the encapsulant 14 flows through the through holes 100 of the carrier 10 and encapsulates the first electronic components 11, the blocking member 13 and the second electronic components 12 at the same time. Therefore, instead of performing encapsulating processes on the first side 10a and the second side 10b of the carrier 10, only a single encapsulating process is required to form the encapsulant 14 encapsulating the first electronic components 11, the blocking member 13 and the second electronic components 12.

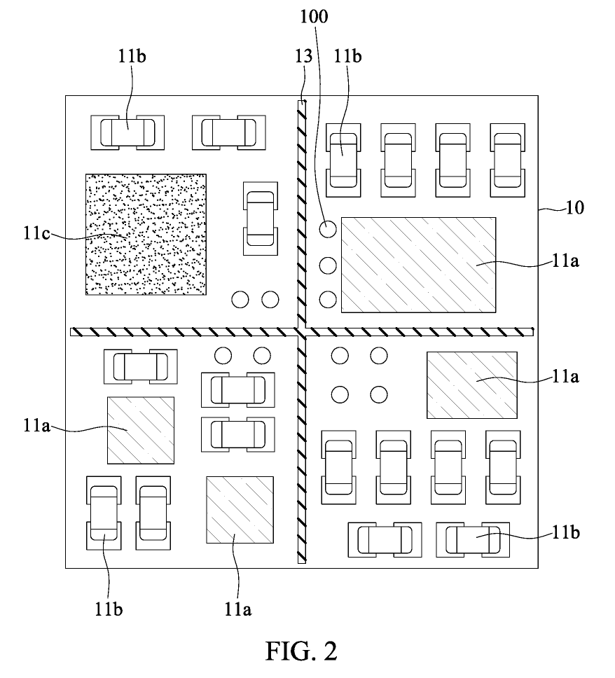

In another embodiment, referring to FIG. 3, no through hole is formed in the carrier 10, an encapsulant 14 is formed on the first side 10a and the second side 10b of the carrier 10, and the entire blocking member 13 is encapsulated by the encapsulant 14, without any portion that is exposed from the encapsulant 14.

Referring to FIG. 1D, a singulation process is performed along cutting paths S of FIG. 1C and a shielding element 15 is disposed on the encapsulant 14 and in contact with the exposed surface of the blocking member 13.

In an embodiment, the shielding element 15 is made of a conductive material, such as metal or conductive adhesive. The shielding element 15 is formed on a surface of the encapsulant 14 by sputtering. In an embodiment, the shielding element 15 is not formed on the second side 10b of the carrier 10. In another embodiment, a conductive lid can serve as the shielding element 15 and cover the encapsulant 14. In an embodiment, the encapsulant 14 is formed first, then at least one through hole is formed in the encapsulant 14, and, subsequently, a conductive material is formed on the surfaces of the encapsulant 14 and in the through hole of the encapsulant 14 so as to form the shielding element 15 and the blocking member 13.

In an embodiment, the shielding element 15 extends to a side surface 10c of the carrier 10 to come into contact with a grounding portion of the carrier 10 such as a grounding portion 300 of FIG. 3. As such, the shielding element 15 and the blocking member 13 achieve a grounding function. In another embodiment, the blocking member 13 is in contact with the grounding portion of the carrier 10 so as for the shielding element 15 and the blocking member 13 to achieve a grounding function.

If the blocking member 13 is not exposed from the encapsulant 14, as shown in FIG. 3, and the shielding element 15 is not electrically connected to the blocking member 13, the shielding element 15 can be in contact with the grounding portion 300 of the carrier 10 and the blocking member 13 can be in contact with another grounding portion 301 of the carrier 10. In an embodiment, the grounding portions 300 and 301 are not electrically connected to each other. As such, the shielding element 15 and the blocking member 13 have separate grounding functions, thus avoiding external electromagnetic interference and also preventing internal electronic components from interfering with one another.

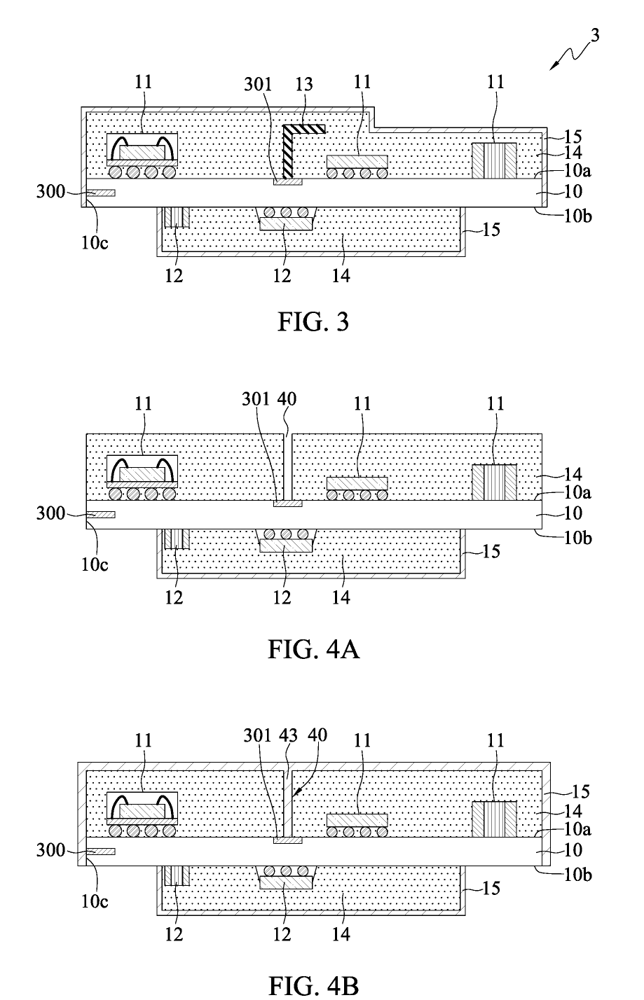

In an embodiment, the blocking member 13 and the shielding element 15 can be integrally formed. Referring to FIGS. 4A and 4B, the encapsulant 14 is formed on the first side 10a and the second side 10b of the carrier 10 to encapsulate the first electronic components 11 and the second electronic components 12. Then, at least one groove 40 is formed in the encapsulant 14 between adjacent two of the first electronic components 11, with a portion of the surface of the first side 10a of the carrier 10 exposed in the groove 40. Then, a sputtering process is performed to integrally form the shielding element 15 on the encapsulant 14 and the blocking member 43 in the groove 40.

According to the present disclosure, the encapsulant 14 can flow through the through holes 100 of the carrier 10 to encapsulate the first electronic components 11, the blocking member 13 and the second electronic components 12. As such, a single encapsulating process can be performed on both the first side 10a and the second side 10b of the carrier 10 so as to form the encapsulant 14 encapsulating the first electronic components 11, the blocking member 13 and the second electronic components 12.

Further, the shielding element 15 formed around an outer periphery of the first and second electronic components 11 and 12 effectively prevents external electromagnetic waves from interfering with internal circuits of the first and second electronic components 11 and 12, thus ensuring proper operation and overall electrical efficiency of the electronic package structure 1.

Furthermore, the blocking member 13 positioned between adjacent two of the first electronic components 11 prevents electromagnetic interference from occurring between the first electronic components 11.

Referring to FIGS. 1D, 3 and 4B, the present disclosure further provides an electronic package structure 1, which has: a carrier 10 having a first side 10a and a second side 10b opposite to the first side 10a; a plurality of first electronic components 11 disposed on the first side 10a of the carrier 10; a plurality of second electronic components 12 disposed on the second side 10b of the carrier 10; at least one blocking member 13, 43 formed on the first side 10a of the carrier 10 between adjacent two of the first electronic components 11; an encapsulant 14 formed on the first side 10a and the second side 10b of the carrier 10 and encapsulating the first electronic components 11, the second electronic components 12 and the blocking member 13, 43; and a shielding element 15 disposed on the encapsulant 14. In an embodiment, referring to FIG. 1D, at least one through hole 100 is formed in the carrier 10 to communicate the first side 10a with the second side 10b, and the encapsulant 14 is further formed in the through hole 100.

In an embodiment, at least one of the first electronic components 11 is an active element, a passive element, a package, or a combination thereof.

In an embodiment, at least one of the second electronic components 12 is an active element, a passive element, a package, or a combination thereof.

In an embodiment, the shielding element 15 is electrically connected to the carrier 10.

In an embodiment, referring to FIGS. 1D and 4B, the shielding element 15 is electrically connected to the blocking member 13, 43.

In an embodiment, referring to FIG. 3, the shielding element 15 is not electrically connected to the blocking member 13.

In an embodiment, referring to FIG. 3, a grounding portion 300 is formed on a side surface 10c of the carrier 10, and the shielding element 15 extends to the side surface 10c of the carrier 10 so as to come into contact with the grounding portion 300.

In an embodiment, referring to FIG. 4B, the shielding element 15 and the blocking member 43 are integrally formed.

In an embodiment, the blocking member 13 is made of a conductive material. In an embodiment, the blocking member 13 is electrically connected to the carrier 10.

In an embodiment, the shielding element 15 is a conductive layer formed on the encapsulant 14.

In an embodiment, the shielding element 15 is a conductive lid covering the encapsulant 14.

According to the present disclosure, the encapsulant can flow through the through hole of the carrier to encapsulate the first electronic components, the blocking member and the second electronic components. As such, only a single encapsulating process is required, thus greatly reducing the fabrication steps and cost.

Further, the blocking member and the shielding element not only prevent electromagnetic interference from occurring between the first electronic components but also effectively prevent external electromagnetic waves from interfering with internal circuits of the first and second electronic components, thus ensuring normal operation and electrical efficiency of the electronic package structure.

The above-described descriptions of the detailed embodiments are only to illustrate the preferred implementation according to the present disclosure, and it is not to limit the scope of the present disclosure. Accordingly, all modifications and variations completed by those with ordinary skill in the art should fall within the scope of present disclosure defined by the appended claims.

1. An electronic package structure, comprising:
a carrier having a first side and a second side opposite to the first side;
a plurality of first electronic components disposed on the first side of the carrier;
at least one second electronic component disposed on the second side of the carrier;
a blocking member disposed on the first side of the carrier and between adjacent two of the first electronic components; and
an encapsulant formed on the first side and the second side of the carrier and encapsulating the first electronic components, the second electronic component and the blocking member, wherein the carrier has a through hole communicating between the first side and the second side of the carrier with the encapsulant formed in the through hole.

2. (canceled)

3. The electronic package structure of claim 1, wherein at least one of the first electronic components is an active component, a passive component, or a package.

4. The electronic package structure of claim 1, wherein the second electronic component is an active component, a passive component, or a package.

5. The electronic package structure of claim 1, further comprising a shielding element disposed on the encapsulant.

6. The electronic package structure of claim 5, wherein the shielding element is electrically connected to the blocking member.

7. The electronic package structure of claim 5, wherein the shielding element is free from being electrically connected to the blocking member.

8. The electronic package structure of claim 5, wherein the shielding element is electrically connected to the carrier.

9. The electronic package structure of claim 5, further comprising a grounding portion formed on a side surface of the carrier with the shielding element extending to the side surface of the carrier and being in contact with the grounding portion.

10. The electronic package structure of claim 5, wherein the shielding element is a conductive layer formed on the encapsulant.

11. The electronic package structure of claim 5, wherein the shielding element is a conductive lid covering the encapsulant.

12. The electronic package structure of claim 5, wherein the shielding element and the blocking member are integrally formed.

13. The electronic package structure of claim 1, wherein the blocking member is made of a conductive material.

14. The electronic package structure of claim 1, wherein the blocking member is electrically connected to the carrier.

15. A method for fabricating an electronic package structure, comprising:
providing a carrier having a first side and a second side opposite to the first side;
disposing a plurality of first electronic components on the first side of the carrier;
disposing at least one second electronic component on the second side of the carrier;
providing a blocking member; and
forming on the first side and the second side of the carrier an encapsulant encapsulating the first electronic components and the second electronic component, wherein the carrier has a through hole communicating between the first side and the second side of the carrier with the encapsulant formed in the through hole.

16. The method of claim 15, wherein the blocking member is disposed on the first side of the carrier and between adjacent two of the first electronic components.

17. The method of claim 15, wherein the encapsulant further encapsulates the blocking member.

18. The method of claim 15, further comprising forming a groove in the encapsulant between adjacent two of the first electronic components with a surface of the first side of the carrier partially exposed from the groove.

19. The method of claim 18, wherein the blocking member is formed in the groove by sputtering.

20. (canceled)

21. The method of claim 15, wherein at least one of the first electronic components is an active component, a passive component, or a package.

22. The method of claim 15, wherein the second electronic component is an active component, a passive component, or a package.

23. The method of claim 15, further comprising forming a shielding element on the encapsulant.

24. The method of claim 23, wherein the shielding element is electrically connected to at least one of the carrier and the blocking member.

25. The method of claim 23, wherein the shielding element is free from being electrically connected to the blocking member.

26. The method of claim 23, wherein the carrier has a grounding portion formed on a side surface thereof with the shielding element extending to the side surface of the carrier and being into contact with the grounding portion.

27. The method of claim 23, wherein the shielding element is a conductive layer formed on the encapsulant by sputtering.

28. The method of claim 23, wherein the shielding element is a conductive lid covering the encapsulant.

29. The method of claim 23, wherein the shielding element and the blocking member are integrally formed.

30. The method of claim 15, wherein the blocking member is made of a conductive material.

31. The method of claim 15, wherein the blocking member is electrically connected to the carrier.
